(19) United States
(12) Patent Application Publication
(10) Pub. No.: US 2024/0407167 A1
(43) Pub. Date: Dec. 5, 2024

(54) THREE-DIMENSIONAL MEMORY DEVICE AND FORMATION METHOD THEREOF

(71) Applicant: Yangtze Memory Technologies Co., Ltd., Wuhan, Hubei (CN)

(72) Inventors: Kun Zhang, Wuhan (CN); Linchun Wu, Wuhan (CN); Wenxi Zhou, Wuhan (CN); Zhiliang Xia, Wuhan (CN)

(21) Appl. No.: 18/491,603

(22) Filed: Oct. 20, 2023

(30) Foreign Application Priority Data
May 30, 2023 (CN) 202310630053.0

(51) Int. Cl. H10B 43/27; H01L 23/522; H01L 23/528; H10B 41/10; H10B 41/27; H10B 41/35; H10B 43/10; H10B 43/35

(52) U.S. Cl. CPC H10B 43/27; H01L 23/5226; H01L 23/5283; H10B 41/10; H10B 41/27; H10B 41/35; H10B 43/10; H10B 43/35

(57) ABSTRACT

Methods, devices, and systems for three-dimensional (3D) memory devices are provided. In one aspect, a method for forming a three-dimensional (3D) semiconductor device includes: forming a first stack structure including a plurality of alternating sacrificial layers and dielectric layers, the first stack structure having a first region and a second region; forming gate line slits extending through the first stack structure in the first region and the second region; forming a contact via extending to a target sacrificial layer in the second region; forming cavities coupled to the contact via through the gate line slits; and forming conductive layers in replace of the sacrificial layers in the cavities and a contact in the contact via by depositing a conductive material in the contact via and the cavities. The 3D semiconductor device includes a second stack structure having the conductive layers and the dielectric layers.

### CROSS-REFERENCE TO RELATED APPLICATIONS

The present application claims the benefit of priority to China Application No. 202310630053.0, filed on May 30, 2023, the content of which is incorporated herein by reference in its entirety.

### TECHNICAL FIELD

The present disclosure generally relates to the technical field of semiconductors, and more particularly to three-dimensional (3D) memory devices and formation methods thereof.

### BACKGROUND

Planar memory cells are scaled to smaller sizes by improving process technologies, circuit designs, programming algorithms, and manufacturing processes. However, as feature sizes of the memory cells approach a lower limit, the planar processes and manufacturing technologies have become challenging and costly. As a result, a memory density of the planar memory cells approaches an upper limit.

To overcome the limitations brought about by 2D or planar NAND memory devices, the industry has developed a 3D NAND memory device with a three-dimensional structure, in which memory cells are arranged on a substrate three-dimensionally to increase the memory density. At present, how to simplify the manufacturing process of the 3D NAND memory device and improve its performance remains a problem to be solved.

### SUMMARY

One aspect of the present disclosure features a method for forming a three-dimensional (3D) semiconductor device. The method includes: forming a first stack structure including a plurality of alternating sacrificial layers and first dielectric layers, where the first stack structure has a first region and a second region; forming gate line slits extending through the first stack structure in the first region and the second region; forming a contact via extending to a target sacrificial layer in the second region; forming cavities coupled to the contact via through the gate line slits; and forming conductive layers in replace of the sacrificial layers in the cavities and a contact in the contact via by depositing a conductive material in the contact via and the cavities. The contact includes a first portion extending from a surface of a second stack structure including the conductive layers and the first dielectric layers to a target conductive layer corresponding to the target sacrificial layer and a second portion covering part of the surface of the second stack structure.

In some implementations, forming the cavities coupled to the contact via through the gate line slits includes: removing part of the sacrificial layers in the second region to form a first cavity coupled to the contact via; and removing the sacrificial layers in the first region to form a second cavity.

In some implementations, the method further includes: before forming the second cavity, forming a sacrificial contact structure covering the first cavity and the contact via.

In some implementations, forming the sacrificial contact structure includes: forming a first insulation layer on sidewalls and bottoms of the contact via and the first cavity; and forming a second insulation layer at openings of the contact via and the first cavity to cover the openings of the contact via and the first cavity, where the first insulation layer is connected with the second insulation layer to form the sacrificial contact structure.

In some implementations, a deposition rate for forming the first insulation layer is smaller than a deposition rate for forming the second insulation layer.

In some implementations, the method further includes: before depositing the conductive material in the contact via and the cavities, depositing high-k dielectric layers and metallic layers in the contact via and the cavities.

In some implementations, forming the conductive layers for replacing the sacrificial layers in the cavities includes: after depositing the conductive material in the contact via and the cavities, performing etching-back to remove the metallic layers and the conductive material covering sidewalls of the gate line slits and to form etching-back recesses in each of the metallic layers and each of the conductive layers adjoining the sidewalls of the gate line slits.

In some implementations, the method further includes: depositing a third insulation layer and an intermediate filling layer in the gate line slits and the etching-back recesses to form gate line slit structures; and depositing the third insulation layer and the intermediate filling layer in the contact via.

In some implementations, forming the contact via extending to the target sacrificial layer includes: etching the first stack structure to a first dielectric layer adjacent to the target sacrificial layer to form an initial contact via; forming a second dielectric layer in the initial contact via, where the second dielectric layer covers sidewalls and a bottom of the initial contact via; etching the second dielectric layer covering the bottom of the initial contact via and the first dielectric layer to expose the target sacrificial layer; and etching an exposed portion of the target sacrificial layer and a portion of the target sacrificial layer around the exposed portion to form the contact via having an extension portion along a direction perpendicular to an extension direction of the initial contact via.

In some implementations, the method further includes: after forming the contact connected to the target conductive layer in the contact via, forming a first connection structure connected with the contact and a second connection structure connected with a channel structure.

In some implementations, forming the first connection structure and the second connection structure includes: forming a third dielectric layer covering the stack structure, the channel structure and the contacts; forming a first opening and a second opening extending through the third dielectric layer, where the first opening exposes the contact, and the second opening exposes the channel structure; and forming the first connection structure in the first opening and forming the second connection structure in the second opening.

In some implementations, the method further includes: before forming the gate line slits, forming a plurality of channel structures extending through the first stack structure, where each of the plurality of channel structures includes a memory film and a semiconductor channel inwards from an inner surface of the channel structure to a center of the channel structure sequentially.

In some implementations, the method further includes: forming a source sacrificial layer and a fourth insulation layer on a semiconductor substrate; removing the source sacrificial layer through the gate line slits to further extend to the semiconductor substrate to form recesses; removing a part of the memory film through the recesses to expose a part of the semiconductor channel; and forming a second conductive layer in the recesses through the gate line slits, where the second conductive layer connects the semiconductor channel of each of the plurality of channel structures.

Another aspect of the present disclosure features a three-dimensional (3D) memory device, including: a stack structure including a plurality of alternating conductive layers and dielectric layers, the stack structure having a first region and a second region; gate line slit structures extending through the stack structure and dividing the stack structure into a plurality of memory blocks; and a contact located in the second region and including a first portion extending from a surface of the stack structure to a target conductive layer of the conductive layer and a second portion covering part of the surface of the stack structure, where a material of the first portion and the second portion of the contact is same as a material of the conductive layers.

In some implementations, the 3D memory device further includes a plurality of channel structures extending through the stack structure, where each of the plurality of channel structures includes a memory film and a semiconductor channel inwards from an inner surface of the channel structure to a center of the channel structure sequentially.

In some implementations, the 3D memory device further includes a first connection structure and a second connection structure, where the first connection structure is connected to the contact, and the second connection structure is connected to the channel structures.

In some implementations, the 3D memory device further includes a second conductive layer between a semiconductor substrate and an insulation layer, where the plurality of channel structures extends into the semiconductor substrate along a direction, and the stack structure is above the insulation layer along the direction,, and where the second conductive layer is coupled to the semiconductor channel of each of the plurality of channel structures.

In some implementations, the gate line slit structures include first sub-portions and second sub-portions, and the contact further at least includes a third portion and a fourth portion, and a material of the first sub-portions of the gate line slit structures is same as a material of the third portion of the contact, and a material of the second sub-portions of the gate line slit structures is same as the fourth portion of the contact.

A further aspect of the present disclosure features a memory system, including: a memory device configured to store data and a memory controller coupled to the memory device and configured to control the memory device. The memory device includes: a stack structure including a plurality of alternate conductive layers and dielectric layers, and having a first region and a second region; gate line slit structures extending through the stack structure and dividing the stack

structure into a plurality of memory blocks; and a contact in the second region and including a first portion extending from a surface of the stack structure to a target conductive layer and a second portion covering a part of the surface of the stack structure, where the first portion and the second portion of the contact include a same material as the conductive layers.

In some implementations, the memory system further includes a host coupled to the memory controller and configured to send or receive the data.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

In order to illustrate the technical solution in the present disclosure more clearly, the drawings to be used in some examples of the present disclosure will be briefly introduced below. Apparently, the drawings in the following description are only drawings of some examples of the present disclosure. Those skilled in the art may also obtain other drawings according to these drawings. In addition, the drawings in the following description may be regarded as schematic diagrams, instead of limiting an actual size of a product, an actual flow of a method, an actual timing of a signal, etc. involved in the examples of the present disclosure.

FIG. 1 is a top view of a semiconductor structure according to examples of the present disclosure;

FIGS. 2(a)-2(s) illustrate cross-sectional views of a semiconductor structure along lines I-I′ and II-II′ in FIG. 1 in operations of a manufacturing method for forming a 3D NAND memory device according to examples of the present disclosure;

FIG. 3 illustrates a flow chart of a manufacturing method for forming a 3D NAND memory device according to examples of the present disclosure; and

FIG. 4 illustrates a block diagram of an example system having a 3D memory device according to examples of the present disclosure.

The present disclosure will be described with reference to the drawings.

### DETAILED DESCRIPTION

The subject matter described herein will be discussed now with reference to examples. It should be understood that these examples are discussed only to enable those skilled in the art to better understand so as to implement the subject matter described herein, instead of limiting the protection scope, applicability or examples set forth in the claims. The functions and arrangement of elements as discussed may be changed without departing from the protection scope of the present disclosure. For each example, various processes or components may be omitted, substituted or added according to the requirements. For example, the described method may be performed in a different order from the described order, and various operations may be added, omitted or combined. In addition, the features described with respect to some examples may be also combined in other examples.

It is to be noted that, references in the specification to “one example”, “an example”, “some examples”, etc., mean that the described example may include a particular feature, structure, or characteristic, but it is not necessary that every example includes the particular feature, structure, or characteristic. Moreover, such phrases do not necessarily refer to the same example. Further, when a particular feature, structure or characteristic is described in connection with an example, it would be within the knowledge of technicians in the relevant field to affect such feature, structure or characteristic in connection with other examples explicitly or not explicitly described.

Terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, the terms, such as “a”, “an”, or “the”, may be also understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part upon context.

It should be readily understood that, “on”, “over” and “above” in the present disclosure should be interpreted in the broadest manner such that “on” not only means “directly on” something but also includes the meaning of “on” something with an intermediate feature or layer therebetween, and that “over” or “above” not only includes the meaning of over or above something but also includes the meaning of over or above something with no intermediate feature or layer therebetween (i.e., directly on something).

Further, spatially relative terms, such as “beneath”, “under”, “below”, “over”, “above”, and the like, may be used herein for ease of description to describe one element or feature's relationship to other elements or features as illustrated in the figures. The spatially relative terms are intended to encompass different orientations of a device in use or operation in addition to the orientation illustrated in the figures. The device may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer, etc.

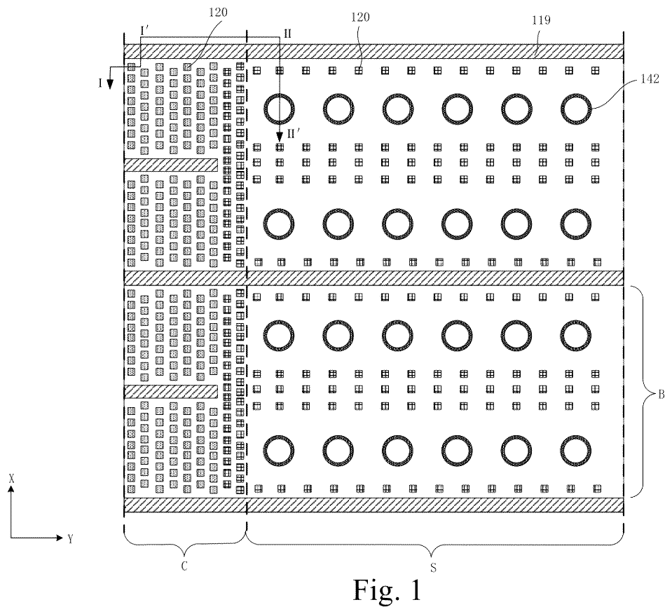

FIG. 1 is a top view of a semiconductor structure 100 according to examples of the present disclosure. As shown in FIG. 1, the semiconductor structure 100 comprises an array region C and a connection region S. The array region C comprises channel structures 120 disposed in an array. As illustrated below, the channel structures 120 comprise NAND memory cell strings. The connection region S comprises contacts 142 and channel structures 120 as dummy channel structures. Gate line slit structures 119 extend a Y direction, and divide the semiconductor structure 100 into a plurality of memory blocks B in an X direction.

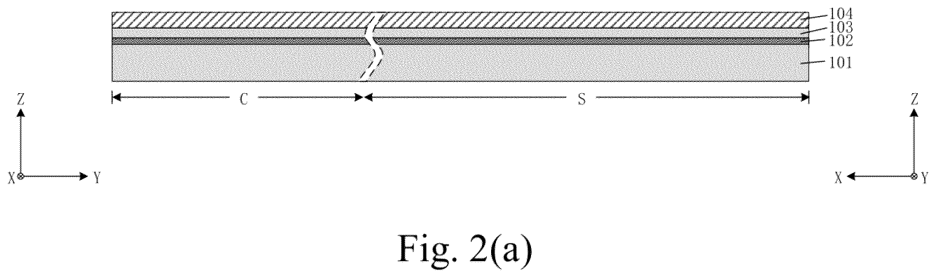

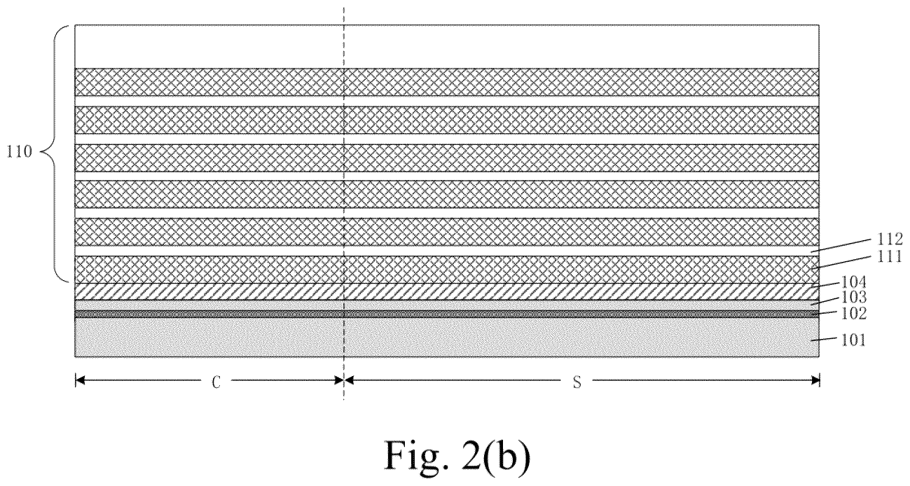

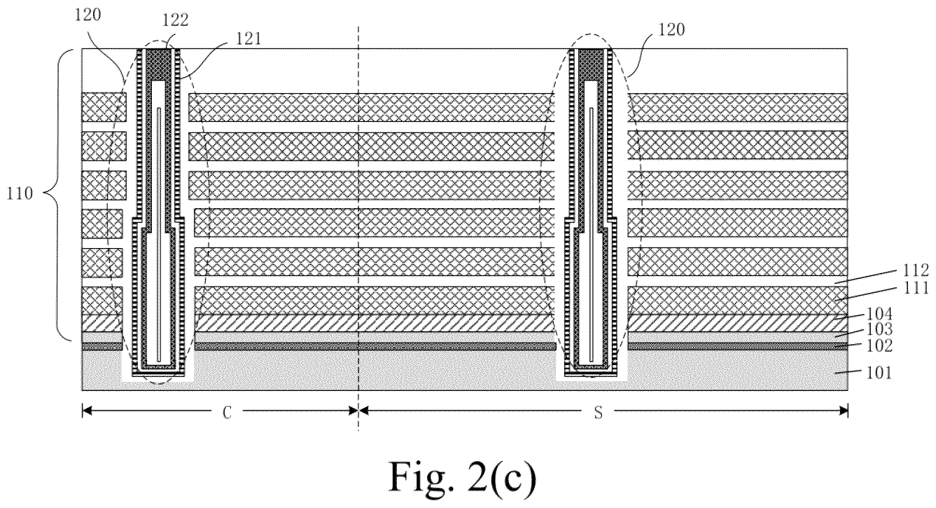

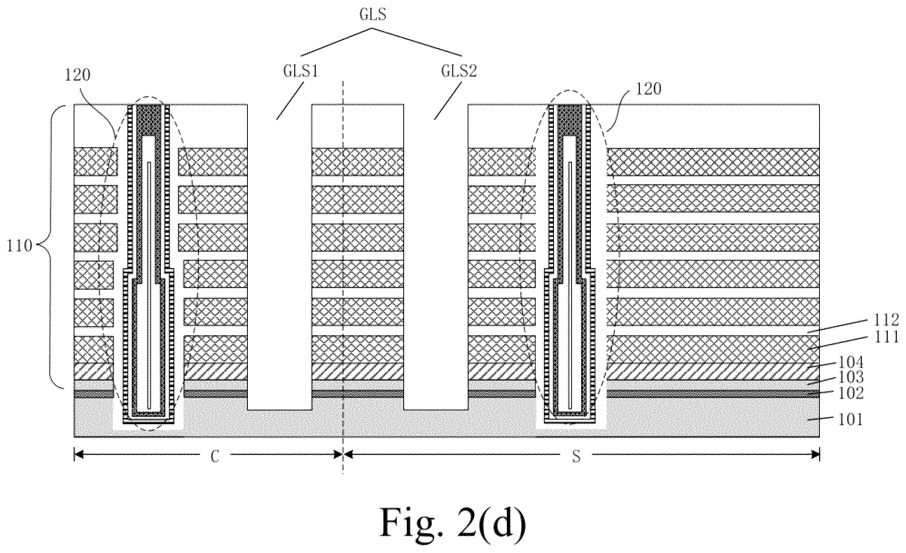

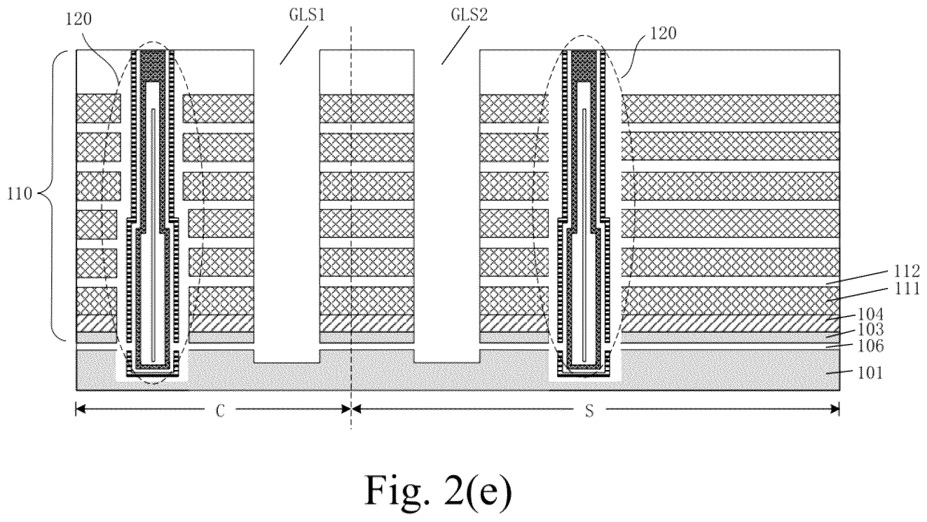

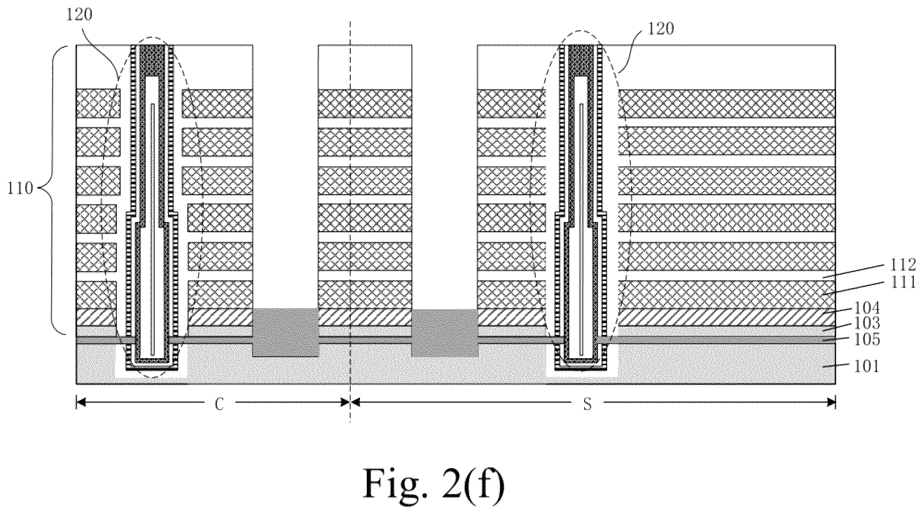

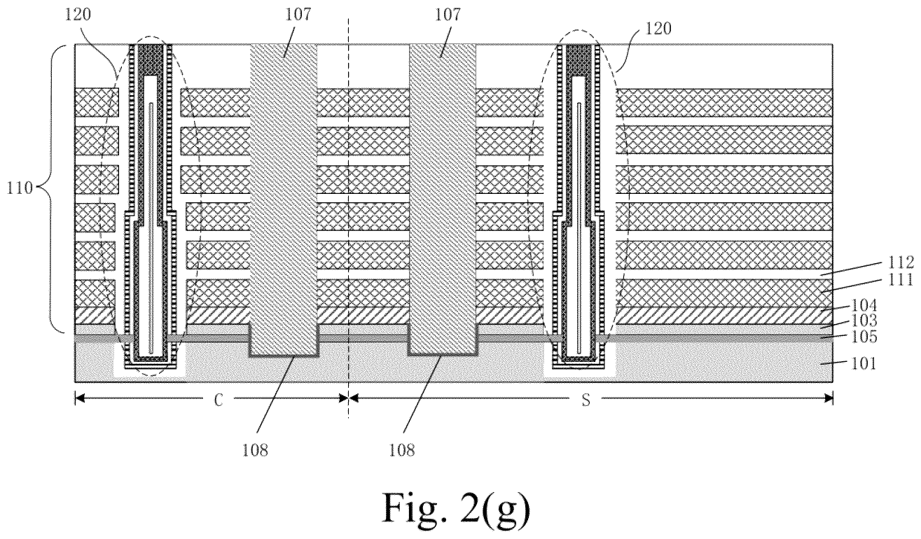

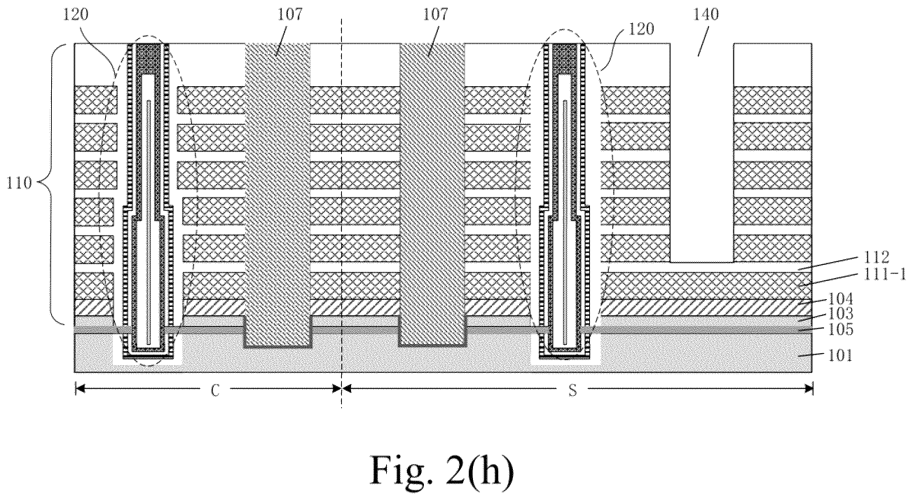

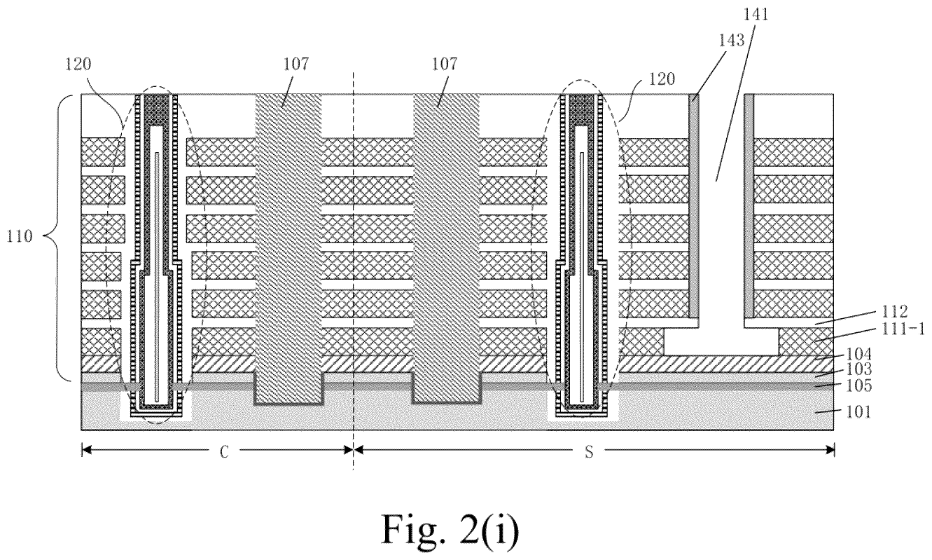

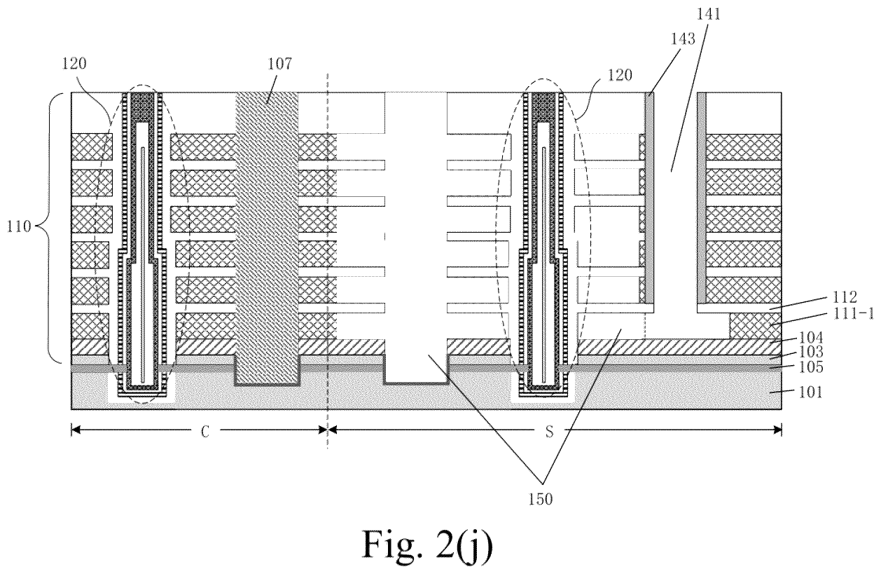

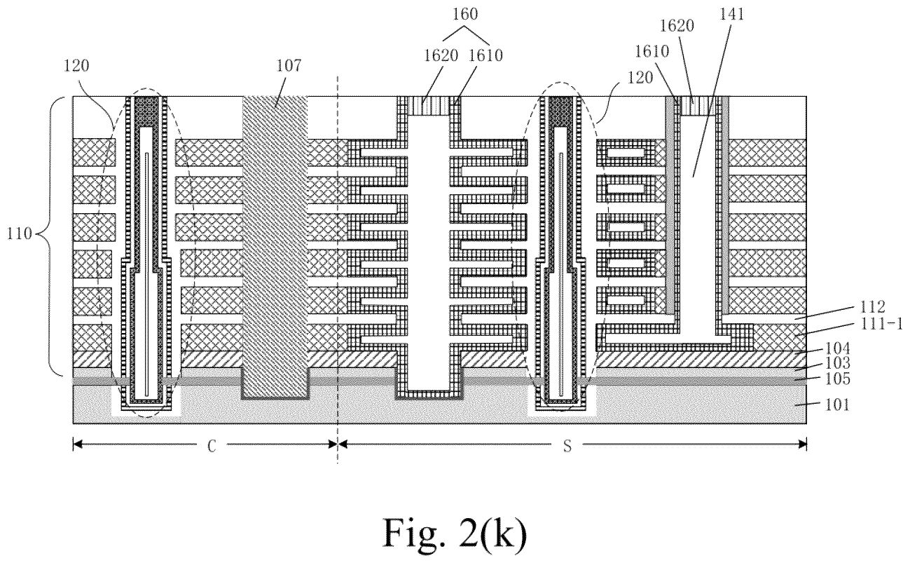

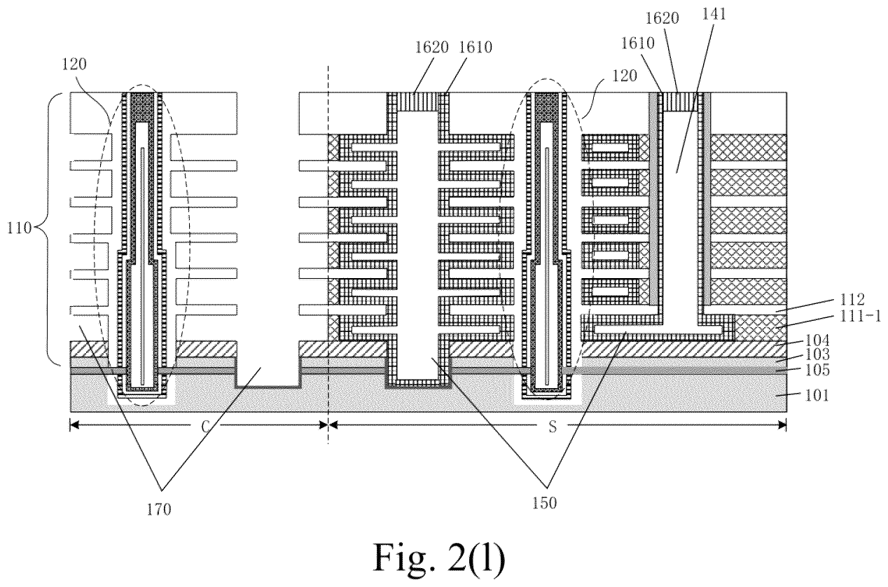

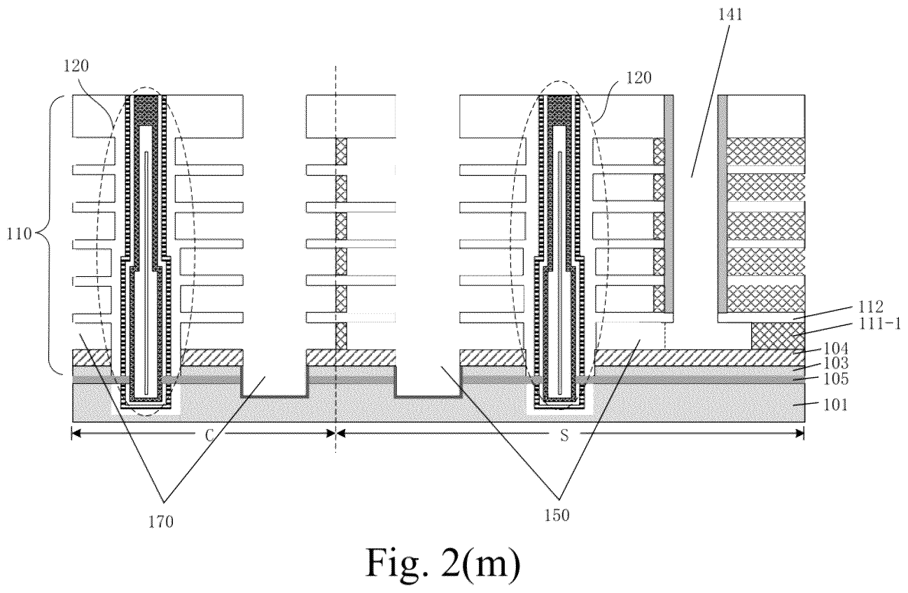

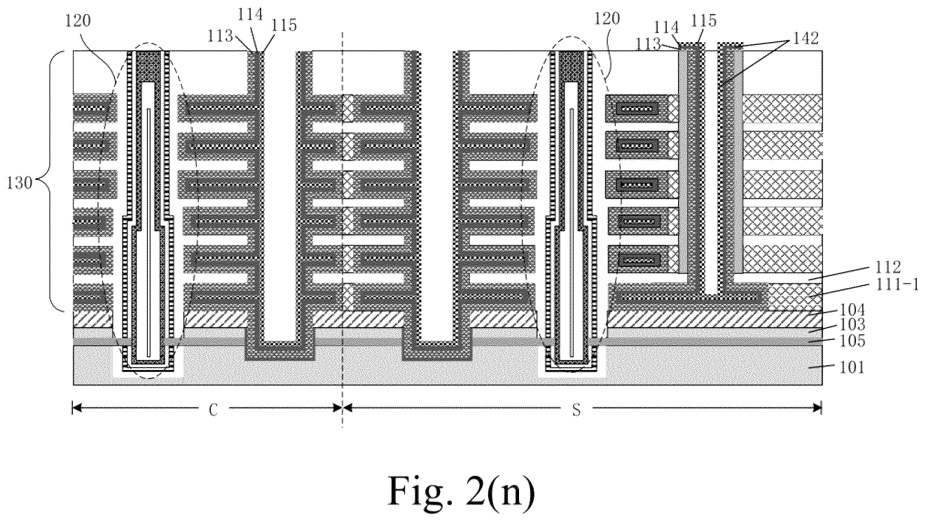

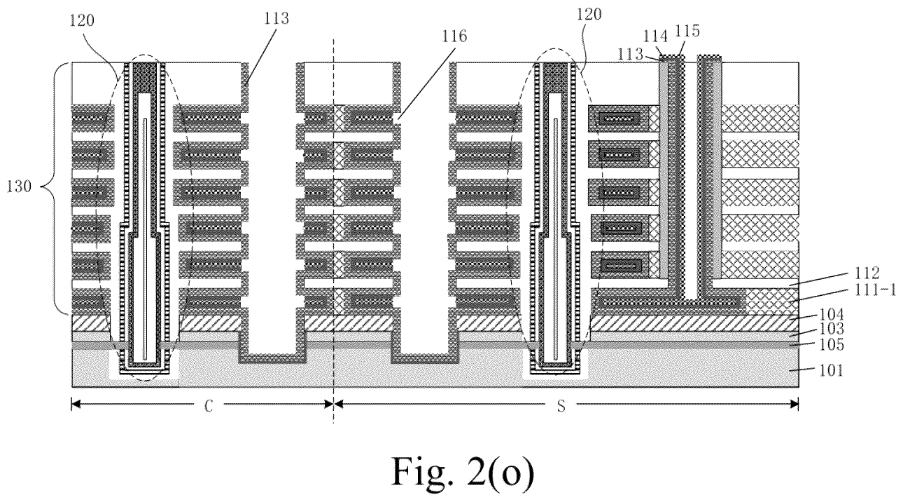

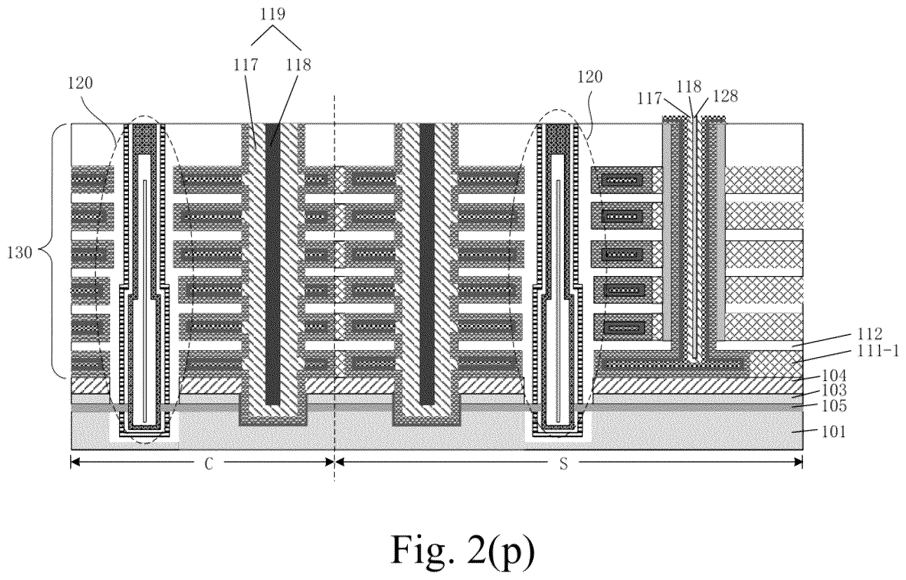

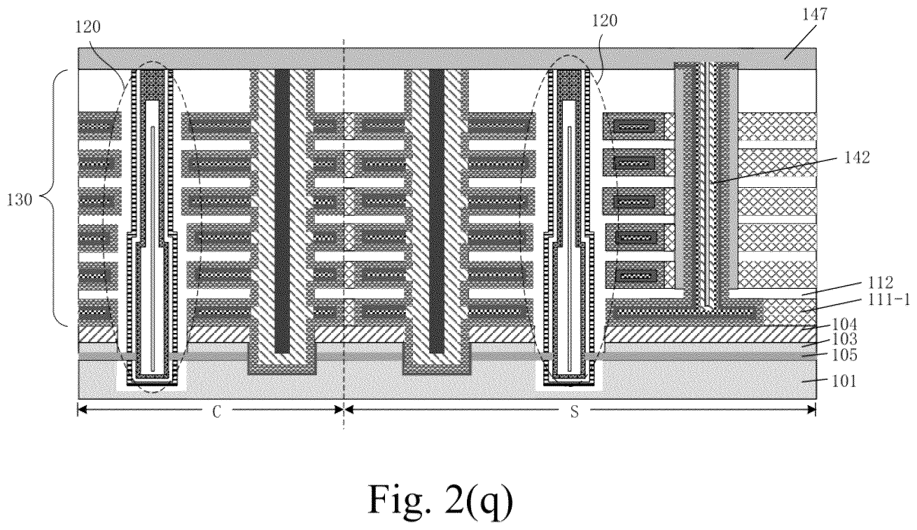

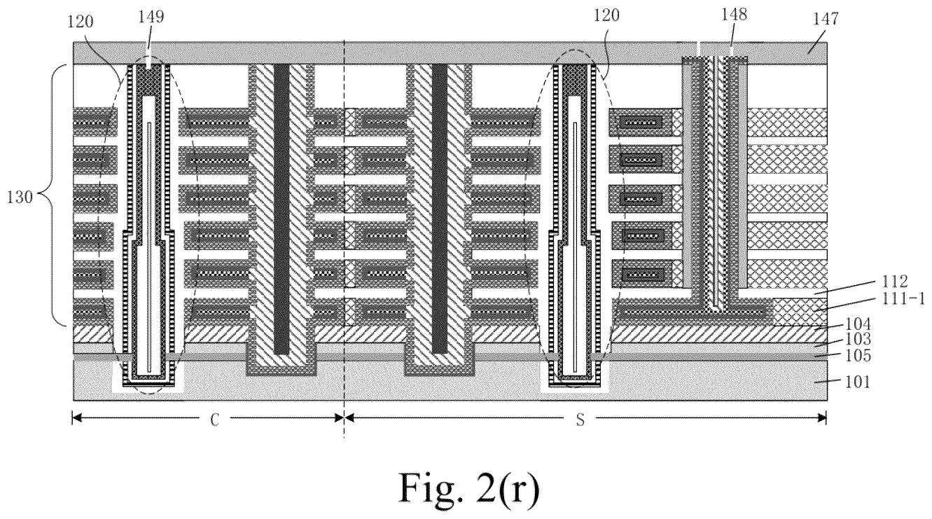

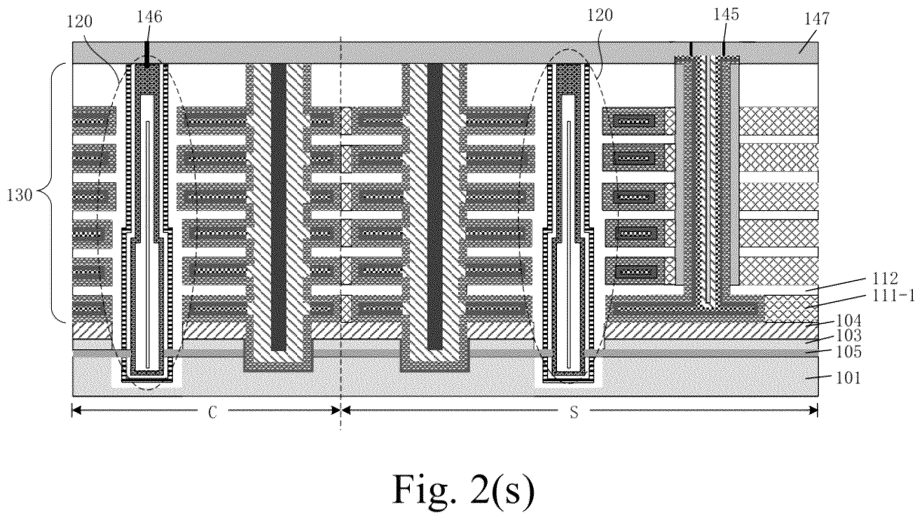

FIGS. 2(a)-2(s) illustrate cross-sectional views of a semiconductor structure along lines I-I′ and II-II′ in FIG. 1 in operations of a manufacturing method for forming a 3D NAND memory device according to examples of the present disclosure. It is to be noted that, FIGS. 2(a)-2(s) illustrate the cross-sectional views along the line I-I′ in FIG. 1 for the array region C, and FIGS. 2(a)-2(s) illustrate the cross-sectional views along the line II-II′ in FIG. 1 for the connection region S. It is apparent to those skilled in the art that the cross-sectional views along the line I-I′ in the array region C and the cross-sectional views along the line II-II′ in the connection region S are cross-sectional views in different directions. For the sake of case of illustration, FIGS. 2(b)-2(s) show the cross-sectional views taken along the lines I-I′ and II-II′ as a whole, while FIG. 2(a) schematically shows that the cross-sectional views taken along the lines I-I′ and II-II′ should be different cross-sectional views.

Referring to FIG. 2(a), in this operation, a semiconductor substrate 101 is provided, and a source sacrificial layer 102, a semiconductor layer 103 and an insulation layer 104 are formed on the semiconductor substrate 101 sequentially. The semiconductor substrate 101 may include silicon (e.g., monocrystalline silicon), silicon germanium (SiGe), gallium arsenide (GaAs), germanium (Ge), silicon on insulator (SOI), germanium on insulator (GOI), or any other suitable semiconductor materials. In some examples, the semiconductor substrate 101 may include a doped polysilicon substrate, for example, may include a P-doped polysilicon substrate or an N-doped polysilicon substrate.

The source sacrificial layer 102 is formed on the semiconductor substrate 101. In some examples, polysilicon or any other suitable sacrificial materials that are removed selectively later may be deposited on a top surface of the semiconductor substrate 101 using one or more thin film deposition processes to form the source sacrificial layer 102. The thin film deposition processes include, but are not limited to, chemical vapor deposition (CVD), physical vapor deposition (PVD), atomic layer deposition (ALD) or any combination thereof.

In an example, the semiconductor layer 103 may be formed on the source sacrificial layer 102 after forming the source sacrificial layer 102, the semiconductor layer 103 may be formed by depositing any suitable semiconductor materials (e.g., polysilicon) using one or more thin film deposition processes, such as CVD, PVD, ALD or any combination thereof. The insulation layer 104 is formed on the semiconductor layer 103 after forming the semiconductor layer 103, the insulation layer 104 may be formed by depositing any suitable insulation materials (e.g., silicon oxide, silicon nitride or silicon oxynitride) using one or more thin film deposition processes, such as CVD, PVD, ALD or any combination thereof.

Next, as shown in FIG. 2(b), an initial stack structure 110 is formed on the insulation layer 104 after forming the insulation layer 104. The initial stack structure 110 comprising a plurality of alternate sacrificial layers 111 and first dielectric layers 112 may be formed on the insulation layer 104. The initial stack structure 110 may be formed by one or more thin film deposition processes, including, but not limited to, CVD, PVD, ALD, or any combination thereof.

According to some examples, the initial stack structure 110 may comprise the plurality of alternate sacrificial layers 111 and first dielectric layers 112. In other words, except a top layer and a bottom layer of the initial stack structure 110, each of the sacrificial layers 111 may be sandwiched between two adjacent ones of the first dielectric layers 112, and each of the first dielectric layers 112 may be sandwiched between two adjacent ones of the sacrificial layers 111. In some examples, the sacrificial layers 111 are replaced by conductive layers subsequently. The first dielectric layers 112 and the sacrificial layers 111 may be deposited on the insulation layer 104 alternately to form the initial stack structure 110. In the same etching process, the sacrificial layers 111 and the first dielectric layers 112 have different etching selectivity ratios with respect to the same etchant, so as to ensure that the first dielectric layers 112 are almost not removed during subsequent removal of the sacrificial layers 111 and replacement of them with the conductive layers. A material of the first dielectric layers 112 may include an insulation material which may include at least one of silicon oxide, silicon nitride, doped silicon oxide, organosilicate glass and an organic insulation material. A material of the sacrificial layers 111 may include at least one of silicon, silicon oxide, silicon carbide and silicon nitride, but the present disclosure is not limited thereto. In an example, example materials for forming the first dielectric layers 112 and the sacrificial layers 111 may include silicon oxide and silicon nitride respectively.

Next, as shown in FIG. 2(c), a plurality of channel structures 120 penetrating through the initial stack structure 110 and extending into the semiconductor substrate 101 are formed. In some examples, forming the channel structures 120 may comprise: first forming channel holes (not shown in FIG. 2(c)) that penetrate through the initial stack structure 110 and extend into the semiconductor substrate 101 through a dry/wet etching process. In an example, the channel holes may have cylindrical or pillar shapes along an extending direction.

The channel structures 120 may be formed in the channel holes after forming the channel holes. Each of the channel structures 120 comprise amemory film 121 and a semiconductor channel 122. In some examples, the memory film 121 comprises a blocking layer, a charge trapping layer and a tunneling layer disposed on sidewalls of the channel holes sequentially. In some examples, a material for the blocking layer may include silicon oxide, silicon nitride, silicon oxynitride, and a high-k dielectric material such as aluminum oxide or hafnium oxide; a material for the charge trapping layer may include polysilicon, silicon nitride, silicon oxynitride, etc.; and a material for the tunneling layer may include silicon oxide, silicon nitride, silicon oxynitride, a high-k dielectric material such as aluminum oxide or hafnium oxide, etc. In an example, the materials of the blocking layer, the charge trapping layer, the tunneling layer and the semiconductor channel 122 may include silicon oxide, silicon nitride, silicon oxide and polysilicon respectively.

In an example, the memory film 121 and the semiconductor channel 122 may be formed in the channel hole by one or more thin film deposition processes such as CVD, PVD, ALD, or any combination thereof. In some examples, a dielectric material may be further filled in remaining spaces of the channel holes and a channel plug may be formed on top of the channel hole far away from the semiconductor substrate 101 after forming the memory film 121 and the semiconductor channel 122.

Next, as shown in FIG. 2(d), a gate line slit GLS penetrating through the initial stack structure 110 and extending into the semiconductor substrate 101 is formed in the array region C and the connection region S. The gate line slit GLS comprises a first portion GLS1 in the array region C and a second portion GLS2 in the connection region S. The gate line slit GLS penetrating through the initial stack structure 110 and extending into the semiconductor substrate 101 may be formed by a dry/wet etching process.

Next, the source sacrificial layer 102 is replaced by a conductive layer 105 via the gate line slit GLS, such that the plurality of semiconductor channels 122 may be electrically connected through sidewalls of the channel structures 120. In order to utilize the conductive layer 105 to replace the source sacrificial layer 102, first as shown in FIG. 2(c), the source sacrificial layer 102 may be removed via the gate line slit GLS to form a lateral recess 106 between the semiconductor substrate 101 and the semiconductor layer 103; then, a part of the memory film 121 is removed to expose part of the semiconductor channel 122 along the sidewall of the channel hole; and then, as shown in FIG. 2(f), a conductive material is deposited into the lateral recess 106 to form the conductive layer 105. In an example, the conductive material may include doped polysilicon. In some examples, the sacrificial layer 102 may be removed by at least one of wet etching or dry etching to form the lateral recess 106. Taking the wet etching as an example, the sacrificial layer 102 may be etched by applying a tetramethylammonium hydroxide (TMAH) etchant via the gate line slit GLS to form the lateral recess 106. In some examples, part of the blocking layer (e.g., including silicon oxide), the charge trapping layer (e.g., including silicon nitride) and the tunneling layer (e.g., including silicon oxide) are etched by applying an etchant (e.g., phosphoric acid for etching silicon nitride and hydrofluoric acid for etching silicon oxide) via the gate line slit GLS and the lateral recess 106, the etching may stop at the semiconductor channel 122.

In some examples, a conductive material may be deposited into the lateral recess 106 via the gate line slit GLS using one or more thin film deposition processes such as CVD, PVD, ALD, or any combination thereof, so as to form the conductive layer 105 in contact with exposed portion of the semiconductor channel 122. Compared with etching SONO structure at bottom of the channel hole and selectively epitaxially growing silicon for electrical connection of the semiconductor channel 122, the conductive layer 105 may contact the semiconductor channel 122 directly from the sidewall of the channel hole. Therefore, the risk of SONO etching brought about by the increase in the number of layers can be reduced, and a process window of the 3D NAND memory device is increased. When the channel structure 120 extends into an N-doping area of the semiconductor substrate 101 and the conductive layer 105 comprises N polysilicon, an SWNN (Side Wall N-poly/N-Sub) structure is formed.

Next, as shown in FIG. 2(g), a sacrificial material 107 is filled in the gate line slit GLS, wherein an insulation layer 108 is formed between the sacrificial material 107 and the substrate 101, the conductive layer 105 and the semiconductor layer 103. In order to form the insulation layer 108, after the conductive layer 105 in the gate line slit GLS is removed by at least one of a dry etching process or a wet etching process, a part of the substrate 101, the conductive layer 105 and the semiconductor layer 103 are etched towards a direction parallel to the substrate 101 along a sidewall of the gate line slit GLS to form a groove. The groove has a larger lateral size than the gate line slit GLS in the direction parallel to the substrate 101. The groove may be formed by a suitable etching process, such as a dry etching or a wet etching. After forming the groove, the insulation layer 108 is formed on the sidewall of the gate line slit GLS and in the groove by a suitable thin film deposition process, including, but not limited to, CVD, PVD, ALD or any combination thereof. A material of the insulation layer 108 may be the same as that of the first dielectric layer 112. Subsequently, the insulation layer 108 on the sidewall of the gate line slit GLS may be removed, while the insulation layer 108 in the groove is remained. Thereafter, the sacrificial material 107 may be deposited into the gate line slit GLS using one or more thin film deposition processes such as CVD, PVD, ALD, or any combination thereof.

Next, a contact via extending to a target sacrificial layer is formed in the connection region S. In order to form the contact via extending to the target sacrificial layer, as shown in FIG. 2(h), the initial stack structure 110 is first etched to the first dielectric layer 112 adjacent to and above the target sacrificial layer 111-1 to form an initial contact via 140. The initial stack structure 110 may be etched by a dry/wet etching process to form the initial contact via 140. In an example, the initial contact via 140 is formed using an anisotropic etching (any one of dry etchings such as plasma etching, reactive ion etching, laser ablation, etc.) process. Next, a second dielectric layer 143 is formed in the initial contact via 140. The second dielectric layer 143 covers a sidewall and a bottom of the initial contact via 140. In some examples, a material of the second dielectric layer 143 may include an insulation material which may include at least one of silicon oxide, silicon nitride, doped silicon oxide, organosilicate glass, dielectric metal oxide (e.g., aluminum oxide, hafnium dioxide, etc.) and an organic insulation material. Next, as shown in FIG. 2(i), the second dielectric layer 143 covering the bottom of the initial contact via 140 and the first dielectric layer 112 therebelow are etched to expose the target sacrificial layer 111-1. In some examples, the material of the second dielectric layer 143 may be the same as the material of the first dielectric layers 112, thus the second dielectric layer 143 covering the bottom of the initial contact via 140 and the first dielectric layer 112 therebelow can be removed through the same etchant and one time of an etching process. Next, as shown in FIG. 2 (i), an exposed portion of the target sacrificial layer 111-1 and a portion around the exposed portion are etched to form the contact via 141 having a lateral extension portion.

Next, as shown in FIG. 2(j), the sacrificial material 107 in the second portion GLS2 of the gate line slit GLS is removed, and part of the sacrificial layers 111 in the connection region S are removed via the second portion GLS2 of the gate line slit GLS to form a first cavity 150 communicated with the contact via 141. In some examples, the sacrificial material 107 in the second portion GLS2 of the gate line slit GLS may be first removed using a dry/wet etching process, and then the part of the sacrificial layers 111 in the connection region S is removed using isotropic etching by utilizing the second portion GLS2 of the gate line slit GLS as an etchant channel, so as to form the first cavity 150 communicated with the contact via 141. Note that, the first cavity 150 comprises the second portion GLS2 of the gate line slit GLS.

Next, as shown in FIG. 2(k), a sacrificial contact structure 160 enclosing the first cavity 150 and the contact via 141 is formed. A first insulation layer 1610 may be formed using one or more thin film deposition processes such as CVD, PVD, ALD, or any combination thereof. The first insulation layer 1610 covers sidewalls and bottoms of the first cavity 150 and the contact via 141. The deposition is stopped after covering the sidewalls and the bottoms of the first cavity 150 and the contact via 141 through openings of the first cavity 150 and the contact via 141 by controlling deposition time, thereby forming the first insulation layer 1610. Then, a second insulation layer 1620 may be formed using one or more thin film deposition processes such as CVD, PVD, ALD, or any combination thereof. The second insulation layer 1620 covers the openings of the first cavity 150 and the contact via 141, the first insulation layer 1610 is connected with the second insulation layer 1620 to form the sacrificial contact structure 160. Here, the second insulation layer 1620 encloses the openings of the first cavity 150 and the contact via 141 to avoid removal of the sacrificial layers 111 in the connection region S and further caused collapse due to an insufficient support force inside the semiconductor device during the subsequent removal of the sacrificial material 107 of the first portion GLS1 of the gate line slit GLS and the removal of the sacrificial layers 111 in the array region C.

A deposition rate of forming the second insulation layer 1620 may be controlled, such that the deposition rate of forming the second insulation layer 1620 is greater than a deposition rate of forming the first insulation layer 1610, which can enclose the openings of the first cavity 150 and the contact via 141. In an example, a material of the first insulation layer 1610 is the same as a material of the second insulation layer 1620. On this basis, the deposition rate of depositing the material may be controlled, for example, the deposition rate is increased after forming the first insulation layer 1610, such that the openings of the first cavity 150 and the contact via 141 may be enclosed in advance to form the second insulation layer 1620. Note that, the material of the first insulation layer 1610 and the material of the second insulation layer 1620 may be the same or may be different. In the case where the material of the first insulation layer 1610 and the material of the second insulation layer 1620 are different, the second insulation layer 1620 further covers an inner wall (not shown in FIG. 2(k)) of the first insulation layer 1610.

Next, as shown in FIG. 2(l), the sacrificial material 107 in the first portion GLS1 of the gate line slit GLS is removed, and the sacrificial layers 111 in the array region C are removed via the first portion GLS1 of the gate line slit GLS to form a second cavity 170. In some examples, the sacrificial material 107 in the first portion GLS1 of the gate line slit GLS may be first removed using a dry/wet etching process, and then the sacrificial layers 111 in the array region C are removed using isotropic etching by utilizing the first portion GLS1 of the gate line slit GLS as an etchant channel, so as to form the second cavity 170. Note that, the second cavity 170 comprises the first portion GLS1 of the gate line slit GLS.

Next, as shown in 2(m), the sacrificial contact structure 160 is removed. The sacrificial contact structure 160 in the first cavity 150 and the contact via 141 may be removed using dry/wet etching, wherein the first cavity 150 is communicated with the contact via 141 at a position of the target sacrificial layer 111-1.

Next, as shown in FIG. 2(n), conductive layers 115 are formed in the first cavity 150 and the second cavity 170 via the first portion GLS1 and the second portion GLS2 of the gate line slit GLS and the contact via 141, and the contact 142 is formed in the contact via 141. A conductive material may be deposited in the first cavity 150, the second cavity 170 and the contact via 141 using one or more thin film deposition processes such as CVD, PVD, ALD, or any combination thereof by utilizing the first portion GLS1 and the second portion GLS2 of the gate line slit GLS and the contact via 141 as a deposition channel, so as to form the conductive layers 115 in the first cavity 150 and the second cavity 170, and form the contact 142 in the contact via 141. The conductive material may include, for example, at least one of tungsten, cobalt, copper, aluminum, doped silicon and silicide. At this point, a stack structure 130 comprising the first dielectric layers 112 and the conductive layers 115 stacked alternately is formed.

In some examples, as shown in FIG. 2(n), before the conductive material is deposited in the first cavity 150, the second cavity 170 and the contact via 141, high-k dielectric layers 113 and metal compound layers 114 are deposited in the first cavity 150, the second cavity 170 and the contact via 141. That is, the high-k dielectric layers 113, the metal compound layers 114 and the conductive layers 115 are deposited in the first cavity 150, the second cavity 170 and the contact via 141 sequentially.

As shown in FIG. 2(n), by using the first portion GLS1 and the second portion GLS2 of the gate line slit GLS as a deposition channel, the high-k dielectric layers 113, the metal compound layers 114 and the conductive layers 115 may be sequentially formed in the first cavity 150 and the second cavity 170 obtained by removing the sacrificial material layers 111 through the first portion GLS1 and the second portion GLS2 of the gate line slit GLS. In addition, the high-k dielectric layers 113, the metal compound layers 114 and the conductive layers 115 are also formed on sidewalls and bottoms of the first portion GLS1 and the second portion GLS2 of the gate line slit GLS. The high-k dielectric layers 113 may be used to reduce the risk of charge in the channel structure 120 flowing to the conductive layers 115. A dielectric constant value of the high-k dielectric layers 113 is greater than or equal to 7. In an example, a material of the high-k dielectric layers 113 includes at least one of aluminum oxide, hafnium oxide and tantalum oxide. The metal compound layers 114 may be configured as adhesion layers to increase an adhesive force between the conductive layers 115 and the first dielectric layers 112. A material of the metal compound layers 114 may include at least one of titanium nitride, tantalum nitride and tungsten carbide.

As shown in FIG. 2(n), the high-k dielectric layers 113, the metal compound layers 114 and the conductive layers 115 may be formed on the sidewall and the bottom of the contact via 141 sequentially using the contact via 141 as a deposition channel, and the high-k dielectric layers 113, the metal compound layers 114 and the conductive layers 115 further cover part of an upper surface of the stack structure 130. Here, part of the high-k dielectric layers 113, the metal compound layers 114 and the conductive layers 115 in the contact via 141 and part of them covering the part of the upper surface of the stack structure 130 form the contact 142.

Next, as shown in FIG. 2(o), etching-back is performed in the first portion GLS1 and the second portion GLS2 of the gate line slit GLS to remove the metal compound layers 114 and the conductive layers 115 covering the sidewalls and the bottoms of the first portion GLS1 and the second portion GLS2 of the gate line slit GLS, and etching-back recesses 116 are formed in each metal compound layer 114 and each conductive layer 115 adjoining the sidewall of the gate line slit GLS. The etching-back may be performed through the first portion GLS1 and the second portion GLS2 of the gate line slit GLS using at least one of a wet etch process or a dry etching process. When the etching-back is performed in the first portion GLS1 and the second portion GLS2 of the gate line slit GLS, the etching-back is not performed in the contact via 141 on the metal compound layers 114 or the conductive layers 115 of the contact 142, which can be achieved by forming a mask layer (not shown) above the contact via 141.

Next, as shown in FIG. 2(p), a third insulation layer 117 and an intermediate filling layer 118 are deposited in the first portion GLS1 and the second portion GLS2 of the gate line slit GLS and the etching-back recesses 116 by continuing using the first portion GLS1 and the second portion GLS2 of the gate line slit GLS and the contact via 141 as a deposition channel, so as to form a first sub-portion and a second sub-portion of the gate line slit structure 119 respectively. Moreover, the third insulation layer 117 and the intermediate filling layer 118 continue to be deposited in the contact via 141, wherein the third insulation layer 117 and the intermediate filling layer 118 in the contact via 141 may form a third portion and a fourth portion of the contact 142 respectively. In some examples, in the case where there is still remaining space after depositing the third insulation layer 117 and the intermediate filling layer 118 in the contact via 141, a filling material, as shown by 128 in FIG. 2(p), may continue to be deposited through the contact via 141.

The third insulation layer 117 of the gate line slit structure 119 is used to prevent short circuits between the different conductive layers 115 and prevent the conductive layers 115 from being oxidized. The intermediate filling layer 118 of the gate line slit structure 119 is used to provide a mechanical support function. Note that, a material of the intermediate filling layer 118 of the gate line slit structure 119 may include a conductive material or include an insulation material. In the case where a source signal needs to be led out through the gate line slit structure 119, the intermediate filling layer 118 of the gate line slit structure 119 may include the conductive material (e.g., polysilicon), and needs to be formed to connect to the conductive layers 105.

Next, a first connection structure 145 connected with the contact 142 and a second connection structure 146 connected with the channel structure 120 are formed. In order to form the first connection structure 145 connected with the contact 142 and the second connection structure 146 connected with the channel structure 120, first, as shown in FIG. 2(q), a third dielectric layer 147 covering the stack structure 130, the channel structure 120 and the contact 142 is formed, the third dielectric layer 147 may include at least one of silicon oxide, silicon nitride, doped silicon oxide, organosilicate glass and an organic insulation material, but the present disclosure is not limited thereto; then, as shown in FIG. 2(r), a first opening 148 and a second opening 149 penetrating through the third dielectric layer 147 may be formed by a dry/wet etching process, the first opening 148 exposes the contact 142, and the second opening 149 exposes the channel structure 120; and at last, as shown in FIG. 2(s), a conductive material (e.g., at least one of tungsten, cobalt, copper, aluminum, doped silicon and silicide) may be deposited in the first opening 148 by using one or more thin film deposition processes such as CVD, PVD, ALD, or any combination thereof to form the first connection structure 145, and the second connection structure 146 is formed in the second opening 149.

So far, the present disclosure provides a manufacturing method for forming a 3D NAND memory device. A conductive material is deposited in the contact via 141 and the cavities 150 and 170 via gate line slits GLS1, GLS2 and the contact via 141, and while the sacrificial layers 111 in the array region C and part of sacrificial layers 111 in the connection region S are replaced by the conductive layers 115, the contact 142 is formed in the contact via 141. That is, the conductive layers 115 and the contacts 142 are formed simultaneously. Since the conductive layers 115 and the contacts 142 are formed simultaneously, a manufacturing process is simplified. Furthermore, in addition to portion extending from an upper surface of a stack structure 130 to a target conductive layer 115, the contact 142 further comprise portion covering part of the upper surface of the stack structure 130, thereby enlarging a footprint of the contact 142, such that the connection structure 145 connected to an external device can be formed more easily. In addition, in the semiconductor device according to examples of the present disclosure, a combination of SWNN with a self-align contact (SCT) architecture is achieved, and the device performance of the 3D NAND memory device is improved.

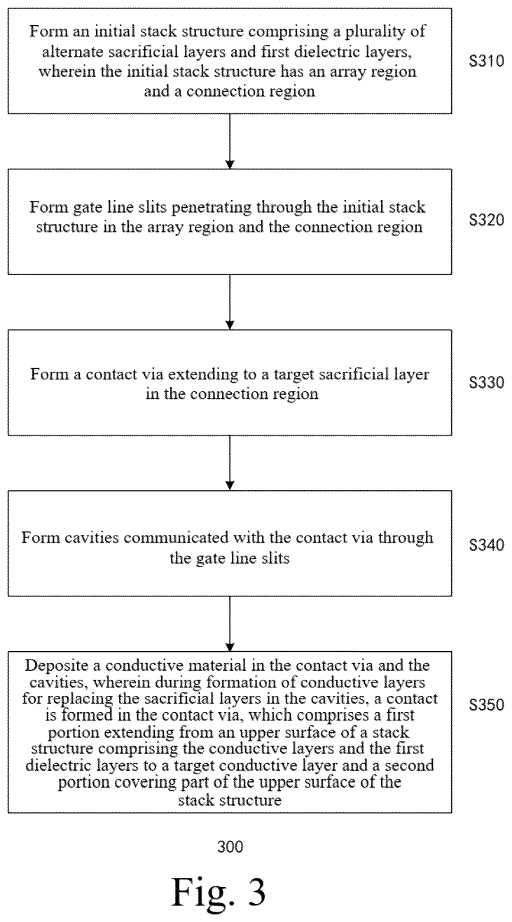

FIG. 3 illustrates a flow chart of a manufacturing method 300 for forming a 3D NAND memory device according to examples of the present disclosure. It should be understood that operations as shown in the method 300 are not exhaustive and that other operations can be performed as well before, after, or between any of the illustrated operations. Furthermore, some of the described operations may be performed simultaneously, or may be performed in a different order from that as shown in FIG. 3.

As shown in FIG. 3, the manufacturing method 300 according to examples of the present disclosure comprises operations S310-S350.

In S310, an initial stack structure comprising a plurality of alternate sacrificial layers and first dielectric layers is formed, the initial stack structure has an array region and a connection region. As shown in FIG. 2(b), the initial stack structure 110 comprising the plurality of alternate sacrificial layers 111 and first dielectric layers 112 is formed, the initial stack structure 110 has the array region C and the connection region S.

In S320, gate line slits penetrating through the initial stack structure are formed in the array region and the connection region. As shown in FIG. 2(d), the gate line slits GLS1, GLS2 penetrating through the initial stack structure 110 are formed in the array region C and the connection region S.

In S330, a contact via extending to a target sacrificial layer is formed in the connection region. As shown in FIGS. 2(h)-2(i), the contact via 141 extending to the target sacrificial layer 111-1 is formed in the connection region S.

In S340, cavities communicated with the contact via are formed through the gate line slits. As shown in FIGS. 2(j)-2(l), the first cavity 150 and the second cavity 170 are formed through the gate line slits GLS1, GLS2, wherein the first cavity 150 is communicated with the contact via 141.

In S350, a conductive material is deposited in the contact via and the cavities; during formation of conductive layers for replacing the sacrificial layers in the cavities, a contact is formed in the contact via, the contact comprises a first portion extending from an upper surface of the stack structure comprising the conductive layers and the first dielectric layers to the target conductive layer and a second portion covering part of the upper surface of the stack structure. As shown in FIGS. 2(m)-2(p), the conductive material is deposited in the first cavity 150, the second cavity 170 and the contact via 141 via the gate line slits GLS1, GLS2 and the contact via 141 to form the conductive layers 115 for replacing the sacrificial layers 111, and the contact 142 is formed at the same time, wherein the contact 142 comprises the first portion extending from the upper surface of the stack structure 130 comprising the conductive layers 115 and the first dielectric layers 112 to the target conductive layer 115 and the second portion covering part of the upper surface of the stack structure 130.

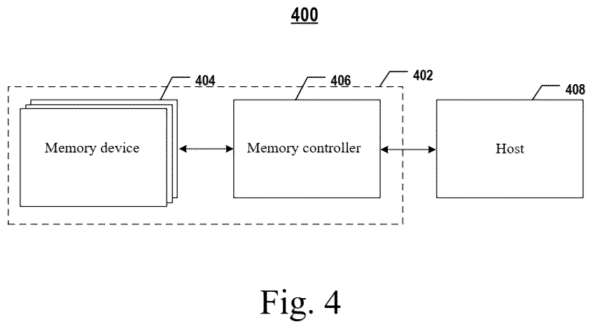

FIG. 4 illustrates a block diagram of an example system 400 having a 3D memory device according to examples of the present disclosure. The system 400 may be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic devices having memory devices therein. As shown in FIG. 4, the system 400 may comprise a host 408 and a memory system 402 having one or more 3D memory devices 404 and a memory controller 406. The host 408 may be a processor of an electronic device, such as a central processing unit (CPU), or a system-on-chip (SoC), such as an application processor (AP). The host 408 may be configured to send or receive data to or from the memory devices 404. In order to send or receive the data to or from the memory devices 404, the host 408 may also send an instruction to the memory system 402 in addition to the data.

The 3D memory devices 404 may be any 3D memory devices/semiconductor structures disclosed in herein. In some examples, each 3D memory device 404 may comprise a NAND flash memory. Consistent with the scope of the present disclosure, conductive layers in a stack structure and contact in a connection region of the 3D memory device 404 are formed simultaneously, which can simplify the manufacturing process. Furthermore, in addition to a first portion extending from an upper surface of the stack structure to a target conductive layer, the contact of the connection region further comprises a second portion covering part of the upper surface of the stack structure, thereby enlarging a footprint of the contact. Therefore, a connection structure connected to an external device can be formed more easily, which will, in turn, improve the performance of the memory system 402 and the system 400.

According to some examples, the memory controller 406 is coupled to the 3D memory devices 404 and the host 408, and is configured to control the 3D memory devices 404. The memory controller 406 can manage the data stored in the 3D memory devices 404 and communicate with the host 408. In some examples, the memory controller 406 is designed for operating in a low duty-cycle environment like secure digital (SD) cards, compact flash (CF) cards, universal serial bus (USB) flash drives, or other media for use in electronic devices, such as personal computers, digital cameras, mobile phones, etc. In some examples, the memory controller 406 is designed for operating in a high duty-cycle environment such as SSDs or embedded multi-media cards (eMMCs) used as data storage for mobile devices, such as smartphones, tablets, laptop computers, etc., and enterprise memory arrays. The memory controller 406 may be configured to control operations of the 3D memory devices 404, such as read, erase, and program operations. The memory controller 406 may also be configured to manage various functions with respect to the data stored or to be stored in the 3D memory devices 404 including, but not limited to, bad-block management, garbage collection, logical-to-physical address conversion, wear leveling, etc. In some examples, the memory controller 406 is further configured to process error correction codes (ECCs) with respect to the data read from or written to the 3D memory devices 404. Any other suitable functions may be performed by the memory controller 406 as well, for example, formatting the 3D memory devices 404. The memory controller 406 may communicate with an external device (e.g., the host 408) according to a particular communication protocol. For example, the memory controller 406 may communicate with the external device through at least one of various interface protocols, such as a USB protocol, an MMC protocol, a peripheral component interconnection (PCI) protocol, a PCI-Express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The foregoing description of the specific examples will completely reveal the general nature of the present disclosure so that others can, by applying knowledge within the skill of the art, readily modify and/or adapt for various applications of such specific examples, without undue experimentation, and without departing from the general concept of the present disclosure. Therefore, such adaptations and modifications are intended to be within the meaning and scope of equivalents of the examples disclosed herein, based on the disclosure and guidance presented herein. It is to be understood that the phrases or terms herein are for the purpose of description and not of limitation, thus the phrases or terms of this specification is to be interpreted by the skilled artisan in light of the disclosure and guidance.

The Summary and Abstract sections can set forth one or more but not all examples of the present disclosure contemplated by the inventor(s), and thus, are not intended to limit the present disclosure and the appended claims in any way.

The breadth and scope of the present disclosure should not be limited by any of the above examples, but should be defined only in accordance with the appended claims and their equivalents.

What is claimed is:

1. A method for forming a three-dimensional (3D) semiconductor device, the method comprising:
forming a first stack structure comprising a plurality of alternating sacrificial layers and first dielectric layers, wherein the first stack structure has a first region and a second region;
forming gate line slits extending through the first stack structure in the first region and the second region;
forming a contact via extending to a target sacrificial layer in the second region;
forming cavities coupled to the contact via through the gate line slits; and
forming conductive layers in replace of the sacrificial layers in the cavities and a contact in the contact via by depositing a conductive material in the contact via and the cavities,
wherein the contact comprises a first portion extending from a surface of a second stack structure comprising the conductive layers and the first dielectric layers to a target conductive layer corresponding to the target sacrificial layer and a second portion covering part of the surface of the second stack structure.

2. The method of claim 1, wherein forming the cavities coupled to the contact via through the gate line slits comprises:
removing part of the sacrificial layers in the second region to form a first cavity coupled to the contact via; and
removing the sacrificial layers in the first region to form a second cavity.

3. The method of claim 2, further comprising:
before forming the second cavity, forming a sacrificial contact structure covering the first cavity and the contact via.

4. The method of claim 3, wherein forming the sacrificial contact structure comprises:
forming a first insulation layer on sidewalls and bottoms of the contact via and the first cavity; and
forming a second insulation layer at openings of the contact via and the first cavity to cover the openings of the contact via and the first cavity, wherein the first insulation layer is connected with the second insulation layer to form the sacrificial contact structure.

5. The method of claim 4, wherein a deposition rate for forming the first insulation layer is smaller than a deposition rate for forming the second insulation layer.

6. The method of claim 1, further comprising:
before depositing the conductive material in the contact via and the cavities, depositing high-k dielectric layers and metallic layers in the contact via and the cavities.

7. The method of claim 6, wherein forming the conductive layers for replacing the sacrificial layers in the cavities comprises:
after depositing the conductive material in the contact via and the cavities, performing etching-back to remove the metallic layers and the conductive material covering sidewalls of the gate line slits and to form etching-back recesses in each of the metallic layers and each of the conductive layers adjoining the sidewalls of the gate line slits.

8. The method of claim 7, further comprising:
depositing a third insulation layer and an intermediate filling layer in the gate line slits and the etching-back recesses to form gate line slit structures; and
depositing the third insulation layer and the intermediate filling layer in the contact via.

9. The method of claim 1, wherein forming the contact via extending to the target sacrificial layer comprises:
etching the first stack structure to a first dielectric layer adjacent to the target sacrificial layer to form an initial contact via;
forming a second dielectric layer in the initial contact via, wherein the second dielectric layer covers sidewalls and a bottom of the initial contact via;
etching the second dielectric layer covering the bottom of the initial contact via and the first dielectric layer to expose the target sacrificial layer; and
etching an exposed portion of the target sacrificial layer and a portion of the target sacrificial layer around the exposed portion to form the contact via having an extension portion along a direction perpendicular to an extension direction of the initial contact via.

10. The method of claim 1, further comprising:
after forming the contact connected to the target conductive layer in the contact via, forming a first connection structure connected with the contact and a second connection structure connected with a channel structure.

11. The method of claim 10, wherein forming the first connection structure and the second connection structure comprises:
forming a third dielectric layer covering the stack structure, the channel structure and the contacts;
forming a first opening and a second opening extending through the third dielectric layer, wherein the first opening exposes the contact, and the second opening exposes the channel structure; and
forming the first connection structure in the first opening and forming the second connection structure in the second opening.

12. The method of claim 1, further comprising:
before forming the gate line slits, forming a plurality of channel structures extending through the first stack structure, wherein each of the plurality of channel structures comprises a memory film and a semiconductor channel inwards from an inner surface of the channel structure to a center of the channel structure sequentially.

13. The method of claim 12, further comprising:
forming a source sacrificial layer and a fourth insulation layer on a semiconductor substrate;
removing the source sacrificial layer through the gate line slits to further extend to the semiconductor substrate to form recesses;
removing a part of the memory film through the recesses to expose a part of the semiconductor channel; and
forming a second conductive layer in the recesses through the gate line slits, wherein the second conductive layer connects the semiconductor channel of each of the plurality of channel structures.

14. A three-dimensional (3D) memory device, comprising:
a stack structure comprising a plurality of alternating conductive layers and dielectric layers, the stack structure having a first region and a second region;
gate line slit structures extending through the stack structure and dividing the stack structure into a plurality of memory blocks; and
a contact located in the second region and comprising a first portion extending from a surface of the stack structure to a target conductive layer of the conductive layer and a second portion covering part of the surface of the stack structure,
wherein a material of the first portion and the second portion of the contact is same as a material of the conductive layers.

15. The 3D memory device of claim 14, further comprising a plurality of channel structures extending through the stack structure,
wherein each of the plurality of channel structures comprises a memory film and a semiconductor channel inwards from an inner surface of the channel structure to a center of the channel structure sequentially.

16. The 3D memory device of claim 15, further comprising a first connection structure and a second connection structure,
wherein the first connection structure is connected to the contact, and the second connection structure is connected to the channel structures.

17. The 3D memory device of claim 15, further comprising a second conductive layer between a semiconductor substrate and an insulation layer,
wherein the plurality of channel structures extends into the semiconductor substrate along a direction, and the stack structure is above the insulation layer along the direction,, and wherein the second conductive layer is coupled to the semiconductor channel of each of the plurality of channel structures.

18. The 3D memory device of claim 14, wherein the gate line slit structures comprise first sub-portions and second sub-portions, and the contact further at least comprises a third portion and a fourth portion, and
wherein a material of the first sub-portions of the gate line slit structures is same as a material of the third portion of the contact, and a material of the second sub-portions of the gate line slit structures is same as the fourth portion of the contact.

19. A memory system, comprising:
a memory device configured to store data, the memory device comprising:
a stack structure comprising a plurality of alternate conductive layers and dielectric layers, and having a first region and a second region;
gate line slit structures extending through the stack structure and dividing the stack structure into a plurality of memory blocks; and
a contact in the second region and comprising a first portion extending from a surface of
the stack structure to a target conductive layer and a second portion covering a part of the surface of the stack structure, wherein the first portion and the second portion of the contact comprise a same material as the conductive layers; and
a memory controller coupled to the memory device and configured to control the memory device.

20. The memory system of claim 19, further comprising a host coupled to the memory controller and configured to send or receive the data.
